(19) United States
(12) Patent Application Publication
(10) Pub. No.: US 2024/0399427 A1
(43) Pub. Date: Dec. 5, 2024

(54) DRAIN CLEANING DEVICE

(71) Applicant: MILWAUKEE ELECTRIC TOOL CORPORATION, Brookfield, WI (US)

(72) Inventors: Justin Miller, Richfield, WI (US); Ka Seng Lim, Milwaukee, WI (US)

(21) Appl. No.: 18/679,726

(22) Filed: May 31, 2024

Related U.S. Application Data
(60) Provisional application No. 63/469,966, filed on May 31, 2023.

(51) Int. Cl. B08B 9/04; H05K 7/20

(52) U.S. Cl. CPC B08B 9/04; H05K 7/20136

(57) ABSTRACT

A drain cleaning device comprising a frame, a drum assembly supported for rotation on the frame about an axis of rotation, a motor supported by the drum assembly, control electronics supported by the drum assembly, and a fan assembly supported by the drum assembly. The motor has an output shaft defining a motor axis. The control electronics define a control electronics axis that is oblique to the motor axis. The fan assembly defines a fan axis, the fan axis being parallel to the control electronics axis. The fan assembly is operable to induce an airflow along the fan axis and the control electronics axis.

### CROSS-REFERENCE TO RELATED APPLICATIONS

This application claims priority to U.S. Provisional Patent Application No. 63/469,966, filed May 31, 2023, the entire contents of which are incorporated herein by reference.

### BACKGROUND OF THE INVENTION

The present application relates to drain cleaning devices for cleaning drains, pipes, or other conduits, and specifically, to a flexible shaft drain cleaner with a fan for cooling interior electronics.

Flexible shaft drain cleaners are known as high speed drain cleaners because they include motors that spin the cable at higher speeds. The higher speed is produced by directly driving the cable with torque from a motor/drive mechanism. In addition, flexible shaft drain cleaners include an improved cable to withstand the higher speeds. Flexible shaft cables are different from traditional drain cleaner cables and typically include a wound cable that is encased by a sheath.

### SUMMARY

In one independent aspect, the invention provides a drain cleaning device including a frame, a drum assembly supported for rotation on the frame about an axis of rotation, a motor supported by the drum assembly, control electronics supported by the drum assembly, and a fan assembly supported by the drum assembly. The motor has an output shaft defining a motor axis. The control electronics define a control electronics axis that is oblique to the motor axis. The fan assembly defines a fan axis, the fan axis being parallel to the control electronics axis. The fan assembly is operable to induce an airflow along the fan axis and the control electronics axis.

In another independent aspect, the invention provides a drain cleaning device including a frame, a drum assembly supported by the frame, a housing supported by the drum assembly, a motor disposed within the housing, and control electronics disposed within the housing. The drum assembly is configured to rotate about an axis of rotation. The control electronics define a control electronics axis. The drain cleaning device further includes a fan assembly disposed within the housing along the control electronics axis. The motor has an output shaft defining a motor axis. The fan assembly is operable to induce an airflow along the control electronics axis.

In another independent aspect, the invention provides a drum assembly including an outer drum and an inner drum coupled for co-rotation with the outer drum, the outer drum and the inner drum defining a space therebetween. The drum assembly further includes a motor supported by the inner drum, control electronics supported by the inner drum, the control electronics defining a control electronics axis, a fan assembly supported by the inner drum along the control electronics axis, and a flexible cable at least partially stored within the space, and a battery receptacle supported by the drum assembly. The motor includes an output shaft defining a motor axis. The battery receptacle is configured to receive a battery pack that supplies power to the motor and to the fan assembly. The control electronics define a control electronics axis wherein the control electronics axis intersects the motor axis at an oblique angle.

Other aspects of the invention will become apparent by consideration of the detailed description and accompanying drawings.

### BRIEF DESCRIPTION OF THE DRAWINGS

FIG. 1 is a front perspective view of a drain cleaning device.

FIG. 2 is a rear perspective view of the drain cleaning device of FIG. 1.

FIG. 3 is a front perspective view of the drain cleaning device of FIG. 1 with portions removed.

FIG. 4 is a cross-sectional view of the drain cleaning device of FIG. 1.

FIG. 5 is another front view of the drain cleaning device of FIG. 1 with portions removed.

FIG. 6 is a rear perspective view of part of the drain cleaning device of FIG. 1 with portions removed.

FIG. 7 is a front view of a fan assembly of the drain cleaning device of FIG. 1.

FIG. 8 is a perspective view of the fan assembly of FIG. 7.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

### DETAILED DESCRIPTION

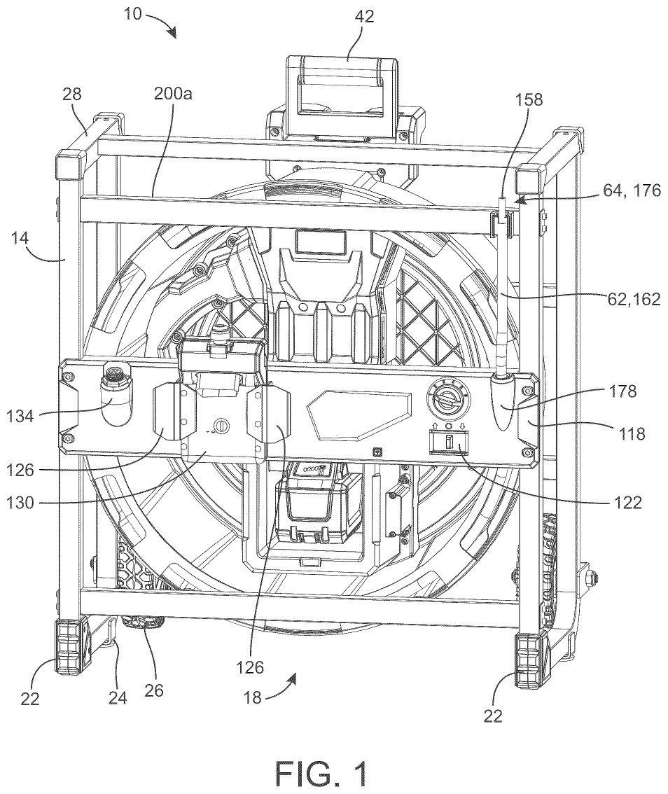

FIGS. 1-8 illustrate a drain cleaning device 10 that includes a fan assembly 116 operable to supply cooling airflow to various components of the drain cleaning device 10, as will be described in further detail below. Although the fan assembly 116 will be described below in the context of the drain cleaning device 10, the fan assembly 116 can equally be applied to other motorized power tools.

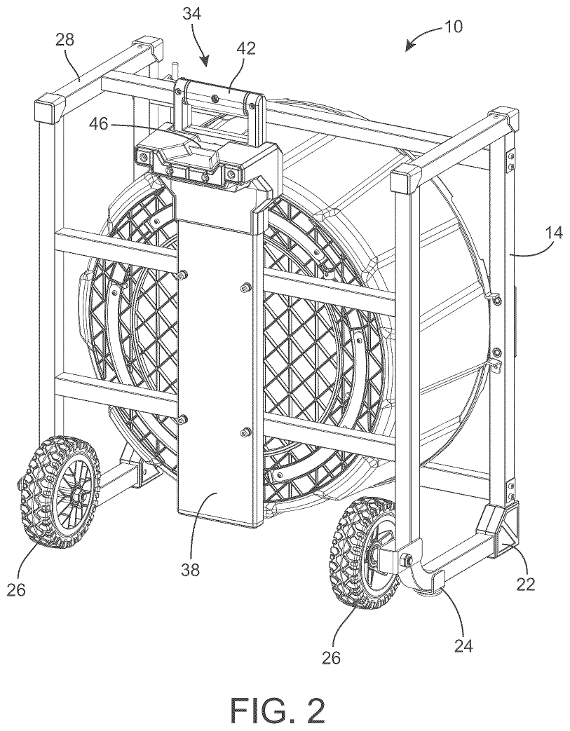

FIGS. 1 and 2 illustrate the drain cleaning device 10 that is operable to clear and clean debris from pipes or other conduits. In the illustrated embodiment, the drain cleaning device 10 is a flexible shaft drain cleaner. The drain cleaning device 10 is operable to spin a drain cleaning cable at a relatively high speed. As described below, the drain cleaning cable may include a wound cable, or other suitable cable, positioned within a sheath. The wound cable is driven (e.g., spun) by the drain cleaning device 10 within the sheath to clear debris from a conduit.

The illustrated drain cleaning device 10 includes a frame 14 and a drum assembly 18 supported by the frame 14. The frame 14 is made from a plurality of bars or links that are coupled together through welding, fasteners, or the like. The bars of the frame 14 are coupled together to form a cage-like structure around the drum assembly 18. In some embodiments, the frame 14 is made from a metal material such as aluminum or steel. In other embodiments, the frame 14 may be made from other materials such as plastic or the like. The frame 14 includes a pair of rubber grommets 22 on a front side to help stabilize the drain cleaning device 10 when the drain cleaning device 10 is in an upright position, as shown in FIG. 1. The frame 14 also includes feet 24 to help further stabilize the drain cleaning device 10 in the upright position. Wheels 26 are coupled to a back side of the frame 14 to facilitate transporting the drain cleaning device 10 across a surface. For example, the drain cleaning device 10 may be tipped onto the wheels 26 (and off of the grommets 22 and feet 24) to move the drain cleaning device 10 along the ground. The illustrated wheels 26 are positioned adjacent, but rearward of the feet 24. In the illustrated embodiment, the wheels 26 are idle (i.e., non-driven wheels). In other embodiments, the wheels 26 may be driven wheels. The drain cleaning device 10 may also be tipped completely onto the wheels 26 and legs 28 of the frame 14 to position the drain cleaning device 10 in a horizontal, operating position. The legs 28 are located adjacent a top side of the frame 14 and extend rearward from the frame 14.

As shown in FIG. 2, a handle assembly 34 is coupled to the frame 14 to facilitate transporting the drain cleaning device 10. The handle assembly 34 includes a handle housing 38 and a handle 42 that is slidable within the handle housing 38 between a retracted position (FIG. 2) and an extended position. An actuator 46 locks the handle 42 in the retracted position to inhibit the handle 42 from unnecessarily being extended out of the handle housing 38. In the illustrated embodiment, the actuator 46 is a button. A user may operate (e.g., depress) the actuator 46 to release the handle 42, allowing the handle 42 to be moved from the retracted position to the extended position. The actuator 46 may then also secure the handle 42 in the extended position. Once the handle 42 is in the extended position, a user may tilt the drain cleaning device 10 onto the wheels 26 and transport the drain cleaning device 10 to a new location. To return the handle 42 to the retracted position, the user may again operate the actuator 46 to release the handle 42, allowing the handle 42 to be moved from the extended position to the retracted position.

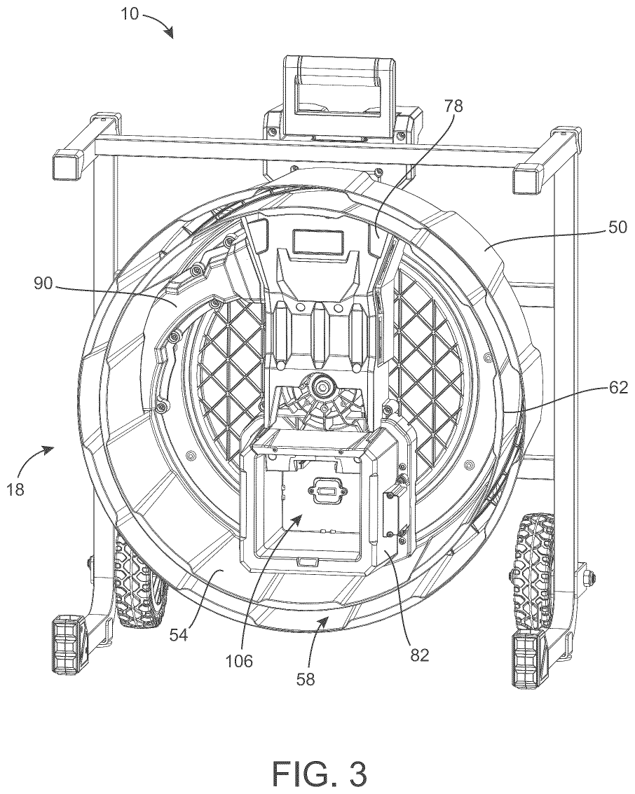

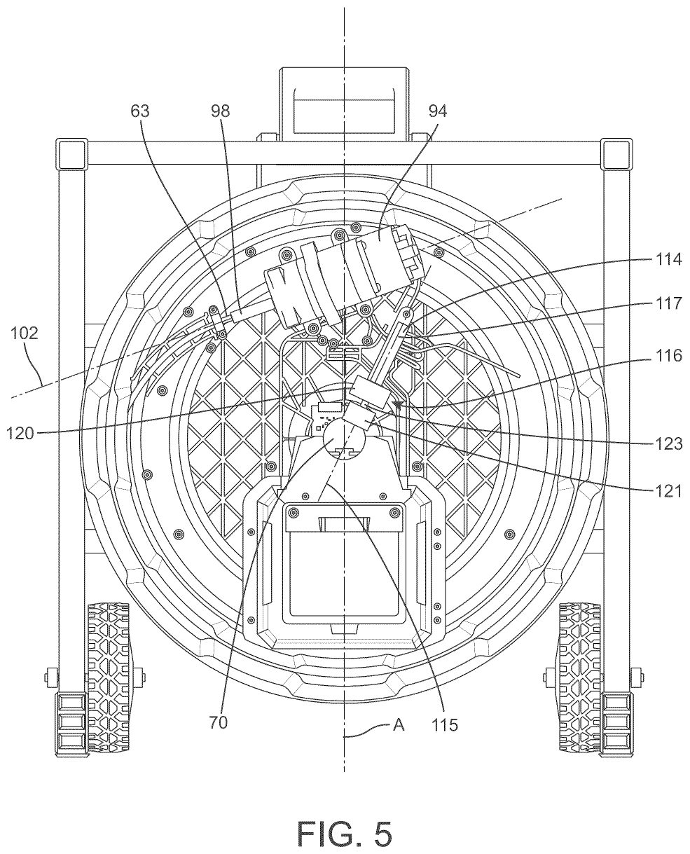

With reference to FIG. 3, the illustrated drum assembly 18 includes an outer drum 50 and an inner drum 54 coupled to the outer drum 50 for co-rotation therewith. In the illustrated embodiment, the outer and inner drums 50, 54 are cylindrical-shaped with an open front end and a closed rear end. In other embodiments, the inner and outer drums 50, 54 may be enclosed to define an interior. In further embodiments, the drum assembly 18 may further include a drum housing that surrounds the inner and outer drums 50, 54. The inner drum 54 has a smaller diameter than the outer drum 50 to define a space 58 therebetween. A drain cleaning cable 62 may be supported within the space 58, as described in more detail below. The drain cleaning cable 62 includes a first end 63 (FIG. 5) and a second end 64 opposite the first end 63 (FIG. 1).

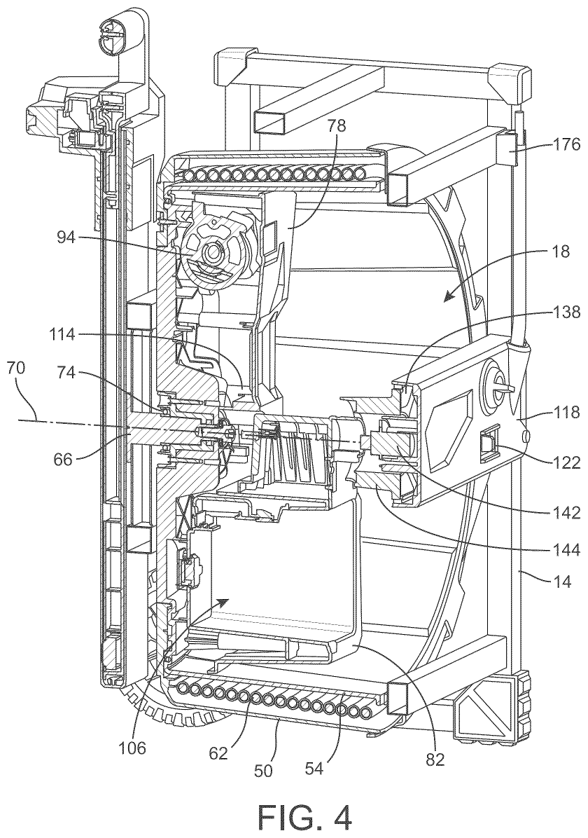

As shown in FIG. 4, the drum assembly 18 is supported on the frame 14 by a support shaft 66. The support shaft 66 includes a first end that is coupled to the frame 14 and a second end that is coupled to the inner drum 54. The support shaft 66 defines an axis of rotation 70 of the drum assembly 18. A bearing 74 is positioned between the inner drum 54 and the support shaft 66 to allow rotation of the inner drum 54 relative to the support shaft 66. In the illustrated embodiment, the drum assembly 18 is idly supported on the support shaft 66. In other words, the drum assembly 18 is allowed to freely rotate on the support shaft 66. In other embodiments, the drum assembly 18 may be driven by a motor to rotate with or about the support shaft 66.

Referring to FIGS. 3 and 4, the inner drum 54 supports a motor housing 78, a battery housing 82, and a guide housing 90. A motor 94 is supported within the motor housing 78. In some embodiments, the motor 94 may be a DC brushless motor. In other embodiments, the motor 94 may include a brush. As shown in FIG. 5, the motor 94 includes an output shaft 98 that defines a motor axis 102. The output shaft 98 is configured to be directly coupled to the first end 63 of the drain cleaning cable 62 to rotate the cable 62. The motor axis 102 is offset from the axis of rotation 70 of the drum assembly 18. More particularly, the motor axis 102 is spaced apart from, but perpendicular to the axis of rotation 70. The motor axis 102 is also orientated at an oblique angle relative to a vertical plane A (when the drain cleaning device 10 is in the upright position) extending through the axis of rotation 70. The vertical plane A extends through the support shaft 66 and the motor 94. The vertical plane A also extends through the battery housing 82. In other embodiments, the output shaft 98 may be oriented in other configurations and/or the motor 94 may be located elsewhere on the drain cleaning device 10.

With reference back to FIGS. 3 and 4, the battery housing 82 defines a battery receptacle 106 configured to receive a battery pack (not shown). In the illustrated embodiment, the battery receptacle 106 is positioned on a diametrically opposite side of the axis of rotation 70 from the motor 94. The battery pack may include any number of different nominal voltages (e.g., 12V, 18V, etc.), and may be configured having any number of different chemistries (e.g., lithium-ion, nickel-cadmium, etc.). The battery pack is operable to supply power to the motor 94 to energize the motor 94. The battery pack is a removable battery pack. The battery pack is also a rechargeable battery pack. Alternatively, the motor 94 may be powered by a remote power source (e.g., a household electrical outlet) through a power cord. In the illustrated embodiment, the battery pack is inserted into the battery receptacle 106 in a direction that is parallel to the axis of rotation 70. As such, the battery pack is mounted with its longitudinal axis parallel with the axis of rotation 70. In other embodiments, the battery pack may be inserted into the battery receptacle 106 in a direction that is perpendicular or oblique to the axis of rotation 70. In further embodiments, the battery receptacle 106 may be positioned elsewhere on the drain cleaning device 10. For example, the battery receptacle 106 may be mounted on the frame 14. In such an embodiment, the battery pack would not spin with the drum during a drain cleaning operation. Further, the battery receptacle 106 may be positioned adjacent the center of the inner drum 54. The battery housing 82 surrounds the battery pack to inhibit fluids or other debris that may be expelled during operation of the drain cleaning device 10 from tampering with the battery pack.

Referring to FIGS. 4 and 5, control electronics 114 are disposed within the motor housing 78. The control electronics 114 are separate from or spaced apart from the motor 94. In other embodiments, the control electronics 114 may be disposed within a separate housing from the motor housing 78. The control electronics 114 may include a controller or processor that controls operation of the drain cleaning device 10. In particular, the controller or processor may be located on one or more printed circuit boards. In some embodiments, the controller is implemented as a microprocessor with separate memory. In other embodiments, the controller may be implemented as a microcontroller (with memory on the same chip). In other embodiments, the controller may be implemented using multiple processors. In addition, the controller may be implemented partially or entirely as, for example, a field-programmable gate array (FPGA), an application specific integrated circuit (ASIC), and the like, and the memory may not be needed or be modified accordingly. The memory may include non-transitory, computer readable memory that stores instructions that are received and executed by the controller to carry out functionality of the drain cleaning device 10 described herein. The memory may include, for example, a program storage area and a data storage area. The program storage area may include combinations of different types of memory, such as read-only memory and random-access memory.

With reference to FIG. 5, the control electronics 114 also include the dedicated fan assembly 116 that provides cooling to the control electronics 114. The fan assembly 116 is disposed within the motor housing 78 and supported by the inner drum 54. In other embodiments, the fan assembly 116 and the control electronics 114 may be disposed within a housing separate from the motor housing 78. The fan assembly 116 may be coupled to a bracket that supports the control electronics 114. In alternative embodiments, the fan assembly 116 may be coupled to a bracket that only supports the fan assembly 116. The fan assembly 116 defines a fan axis 115. The fan axis 115 is the axis about which the fan assembly 116 rotates. The fan axis 115 is also the axis along which air is propelled by the fan assembly 116. In the illustrated embodiment, the fan axis 115 is coaxial to a control electronics axis 117, on which the control electronics 114 are situated. The control electronics axis 117 is a longitudinal axis of the control electronics 114. For example, the control electronics axis 117 may be a central longitudinal axis of the printed circuit board(s) on which the control electronics 114 are located. The fan assembly 116 is disposed along the control electronics axis 117 to cool the control electronics 114 during operation of the drain cleaning device 10. In alternate embodiments, the fan assembly 116 may be parallel to, but offset from the control electronics axis 117. In further embodiments, the fan assembly 116 and fan axis 115 may be perpendicular to the control electronics axis 117. In any scenario, the fan assembly 116 may induce an airflow along one or both faces of the printed circuit board(s) on which the control electronics 114 are located.

In the illustrated embodiment, the fan axis 115 intersects the motor axis 102 at an oblique angle. In alternate embodiments, the fan axis 115 and the motor axis 102 may be perpendicular. However, it should be noted that the fan assembly 116 and the control electronics 114 are adjacent to but separate from the motor 94. As such, the fan assembly 116 is specifically dedicated to provide cooling to the control electronics 114 separate from the motor 94. The motor 94 may include its own dedicated fan that is mounted on and rotates with the output shaft 98. In other embodiments, the fan assembly 116 may also provide cooling to the motor 94. Further, the fan axis 115 and the control electronics axis 117 are offset from the axis of rotation 70 of the drum assembly 18. More particularly, the fan axis 115 and the control electronics axis 117 are spaced apart from, but perpendicular to the axis of rotation 70. The fan axis 115 and the control electronics axis 117 are also orientated at an oblique angle relative to the vertical plane A (when the drain cleaning device 10 is in the upright position) extending through the axis of rotation 70.

The illustrated fan assembly 116 further includes a fan body 120 having a square shape. In alternative embodiments, the fan body 120 could be annular or rectangular in shape. The fan assembly 116 rotates about the fan axis 115 and is driven by a fan motor 121 by way of a fan output shaft 123. The fan motor 121 may be a brushed motor, a brushless motor, or any other motor known for use in fans. In the present embodiment, the fan motor 121 is disposed within the motor housing 78. In other embodiments, the fan motor 121 may be disposed within the fan body 120. In alternate embodiments, the fan motor 121 may be partially disposed within a separate fan motor housing (not shown). Alternatively, the fan motor 121 may be fully enclosed in the fan motor housing. The fan motor housing may be waterproof or dust-proof. The fan motor 121 may be powered by the battery pack or a separate dedicated power source.

With reference back to FIG. 1, a control panel 118 is supported on the frame 14. The illustrated control panel 118 is positioned in front of the drum assembly 18. The control panel 118 includes a user interface 122. The user interface 122 may include, for example, a control switch or other suitable actuators. The user interface 122 may be selectively actuated to control operation of the drain cleaning device 10. For example, a user may toggle the user interface 122 to change the rotation direction of the output shaft 98 when the motor 94 is energized. Additionally, the user interface 122 may be a master power switch to turn the drain cleaning device 10 on and off. In other embodiments, the user interface 122 may control other operations of the drain cleaning device 10. In some embodiments, the fan assembly 116 may be turned on when the drain cleaning device 10 is turned on to begin cooling the control electronics 114. In other embodiments, the fan assembly 116 may be turned on when the motor 94 is activated.

The illustrated control panel 118 also includes clips 126 to support a foot pedal 130. Although not shown, a power cord may be coupled at one end to the foot pedal 130 and at another end to an outlet 134 on the control panel 118. The foot pedal 130 is removable from the control panel 118 to allow a user to remotely control the drain cleaning device 10 (e.g., near an opening through which the cable 62 is inserted). In the illustrated embodiment, the foot pedal 130 may be depressed to activate the motor 94. In some embodiments, the foot pedal 130 may include a switch to change the rotation direction of the motor 94, and thereby the cable 62. In other embodiments, the foot pedal 130 may include a variable speed mechanism to control the speed that the motor 94 rotates the cable 62. For example, the motor 94 may vary the rotation speed of the cable 62 based on how far the foot pedal 130 is depressed. In some embodiments, the control electronics 114 control the output speed of the motor 94 and thus the speed the cable 62 rotates (i.e., variable speed control). In such an embodiment, the control panel 118 may include a variable speed control actuator to adjust the output speed of the motor 94 and thus the cable 62. The variable speed control actuator may be a rotatable knob that may be set to a specific speed level (e.g., speed levels 1-10). In other embodiments, the variable speed control actuator may be positioned on the frame 14, the handle assembly 34, or another location on the drain cleaning device 10.

Referring to FIG. 4, in the illustrated embodiment, the control panel 118 defines an interior 138 that houses electrical components of the user interface 122 and the foot pedal 130. Specifically, the user interface 122 and the foot pedal 130 include electrical wires that are routed through the interior 138 of the control panel 118 to control electronics 114 in the motor housing 78. A slip ring 142 is positioned between the control panel 118 and the motor housing 78 to inhibit the electrical cables that extend between the control panel 118 and the motor housing 78 from tangling during rotation of the drum assembly 18. A shroud 144 surrounds the slip ring 142 to protect debris and contaminants from interfering with the electrical cables passing through the slip ring 142. The shroud 144 rotates with the drum assembly 18 during operation of the drain cleaning device 10 while the slip ring 142 remains stationary. The slip ring 142 also helps support the front side of the drum assembly 18. In some embodiments, the battery receptacle 106 may be supported on the control panel 118. In such an embodiment, power may be transferred from the battery pack to the motor 94 via electrical wires that pass through the slip ring 142. In further embodiments, the slip ring 142 may be positioned adjacent the support shaft 66 to allow electrical wires to pass through the back of the drum assembly 18 to the motor 94 or control electronics 114.

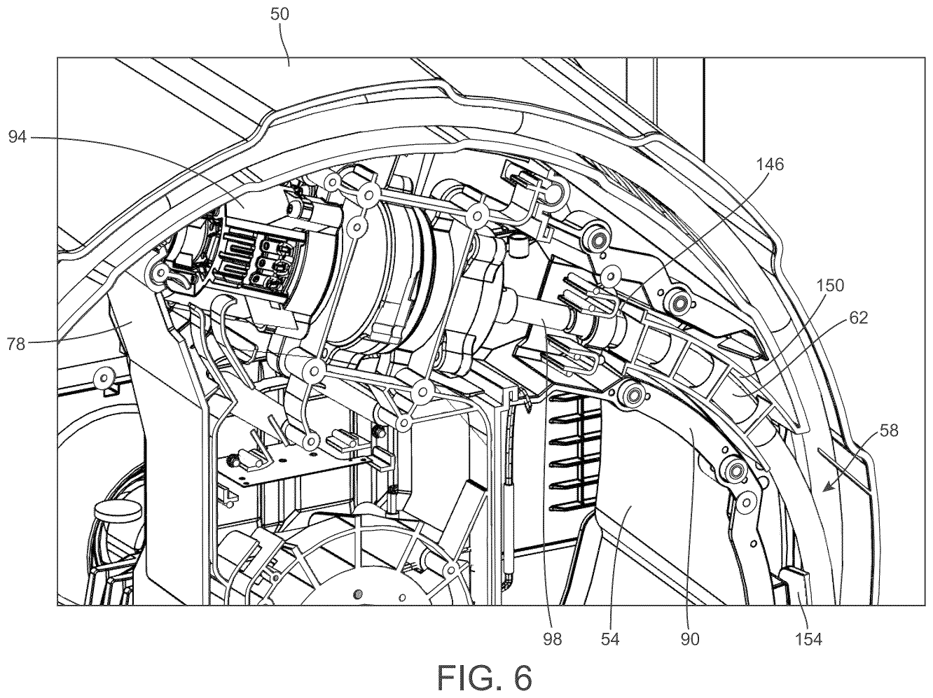

With reference to FIG. 6, the guide housing 90 is coupled to the inner drum 54 adjacent the motor housing 78. The guide housing 90 defines a cavity 146 and a guide channel 150 extending from the cavity 146. The output shaft 98 of the motor 94 extends from the motor housing 78 into the cavity 146 in a direction that is aligned with the guide channel 150. The guide channel 150 terminates adjacent an opening 154 in the inner drum 54 that extends into the space 58 defined between the inner and outer drums 50, 54.

In the illustrated embodiment, the drain cleaning cable 62 is also known as a flexible shaft cable. Compared to typical drain cleaning cables, the flexible shaft cable 62 includes a wound cable 158 that is encased by a sheath 162 (FIG. 1). The wound cable 158 is operable to be rotated by the motor 94 within the sheath 162. The flexible shaft cable 62 includes the first end 63 that is coupled to the motor 94 and the second end 64 that is operable to be extended into a drain to facilitate clearing the drain. Specifically, the wound cable 158 is directly coupled to the output shaft 98 of the motor 94 at the first end 63 of the cable 62 to rotate the wound cable 158 within the sheath 162. The portion of the cable 62 between the first and second ends 63, 64 extends from the output shaft 98 through the guide channel 150 and the opening 154 in the inner drum 54 to be coiled within the space 58 between the inner and outer drums 50, 54. The second end 64 of the cable 62 extends from the space 58 and through an outlet tube 178 (FIG. 1) disposed on the control panel 118. The outlet tube 178 assists a user in directing the cable 62 into a conduit. The second end 64 of the cable 62 may be supported by a receptacle 176 (FIG. 1) positioned on the frame 14 of the drain cleaning device 10 when the drain cleaning device 10 is not in use. In some embodiments, a cable accessory may be coupled to the second end 64 of the cable 62. In some embodiments, the stiffness of the cable 62 depends on the size of the drum assembly 18. For example, for an outer drum 50 with a larger diameter, a cable having a higher stiffness will have less energy loss during operation of the drain cleaning device 10. As such, a ratio of the cable stiffness, in Newtons per millimeter (N/mm), to diameter of the drum, in inches (in.), is between 0.25 and 1.0. In some embodiments, the ratio of the cable stiffness to diameter of the drum is between 0.5 and 0.75. In further embodiments, the ratio of the cable stiffness to diameter of the drum may be more than 1.0 or less than 0.25.

In the illustrated embodiment, the output shaft 98 of the motor 94 directly drives the wound cable 158 to rotate within the sheath 162. In other embodiments, the drain cleaning device 10 may include a transmission to transfer rotation from the output shaft 98 to the cable 62. The transmission may include a gear system to transfer torque from the motor 94 to the cable 62. For example, the transmission may include a planetary gear system including a single stage or multiple stages, a planetary gearset with a bevel gear set, a planetary gearset with two bevel gearsets, only two bevel gearsets, a spur gearset, a helical gearset, a multi-speed gearbox, or a continuously variable gearbox.

In some embodiments, the drain cleaning device 10 includes a clutch disposed between the output shaft 98 of the motor 94 and the first end 63 of the cable 62. The clutch is operable to allow slip between the output shaft 98 and the cable 62 if the output torque of the motor 94 exceeds a predetermined limit to protect the cable 62. In other embodiments, the clutch may be an electronic clutch that senses the output torque of the motor 94 by, for example, sensing the current supplied to the motor 94 from the battery pack. The electronic clutch may then allow slip to occur if the electronic clutch senses that the output torque from the motor 94 was above a predetermined limit. Alternatively, the electronic clutch may sense when the current is above the predetermined limit and communicate with the control electronics 114 to depower the drain cleaning device 10.

During operation of the drain cleaning device 10, a user may extend the second end 64 of the cable 62 into a drain or other conduit. As the cable 62 is payed out from the drum assembly 18, the drum assembly 18 rotates in a first direction. Once the second end 64 of the cable 62 encounters a clog, the user may depress the foot pedal 130 to activate the motor 94 and rotate the wound cable 158 within the sheath 162. Based on the user interface 122, the wound cable 158 will spin either clockwise or counterclockwise within the sheath 162. As the wound cable 158 rotates, the cable accessory assists in removing the debris or clog. Alternatively, a user may force the second end 64 of the cable 62 past the debris within a drain first before activating the motor 94. Then, the user may depress the foot pedal 130 to activate the motor 94 while retracting the cable 62 out of the drain. The motor 94 rotates the wound cable 158 and thus the cable accessory to remove the debris or clog. While the cable 62 is being retracted from the drain, the drum assembly 18 rotates in a second direction, opposite the first direction, to wind the cable 62 back within the space 58. In some embodiments, the drain cleaning device 10 may include a sensor that detects when the cable 62 is being retracted from a drain. The sensor then communicates with the control electronics 114 to automatically activate the motor 94 to rotate the wound cable 158. For example, the sensor may detect that the drum assembly 18 is spinning in the second direction and activate the motor 94. Alternatively, the sensor may be positioned on the cable 62 to detect rearward movement of the cable 62. Once the drain has been sufficiently removed of debris and clogs, the user can then retract the cable 62 from the drain to store the cable 62 within the drum assembly 18.

In some embodiments, the control electronics 114 may include a wireless communication device to communicate with an external device, such as a smart phone or tablet. The wireless communication device communicates with the control electronics 114 based on user input from the external device. For example, a user may use the external device to define operating parameters of the drain cleaning device 10 such as minimum and maximum torque or revolutions per minutes of the output shaft 98 of the motor 94.

Providing a drain cleaning device 10 with a motor 94 that directly drives a cable 62 allows the cable 62 to rotate at higher torque compared to drain cleaning devices that rely on driving a drum assembly to produce friction to rotate the cable. Rotating the cable 62 at higher torque more efficiently cleans a drain or other conduit.

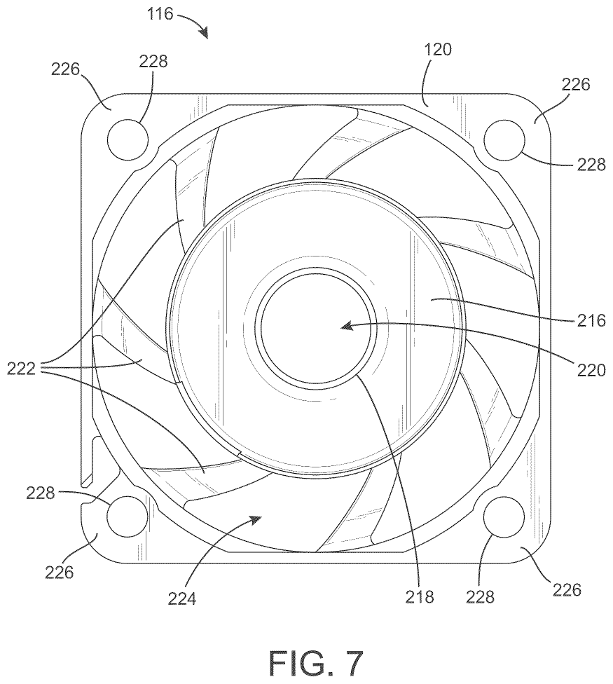

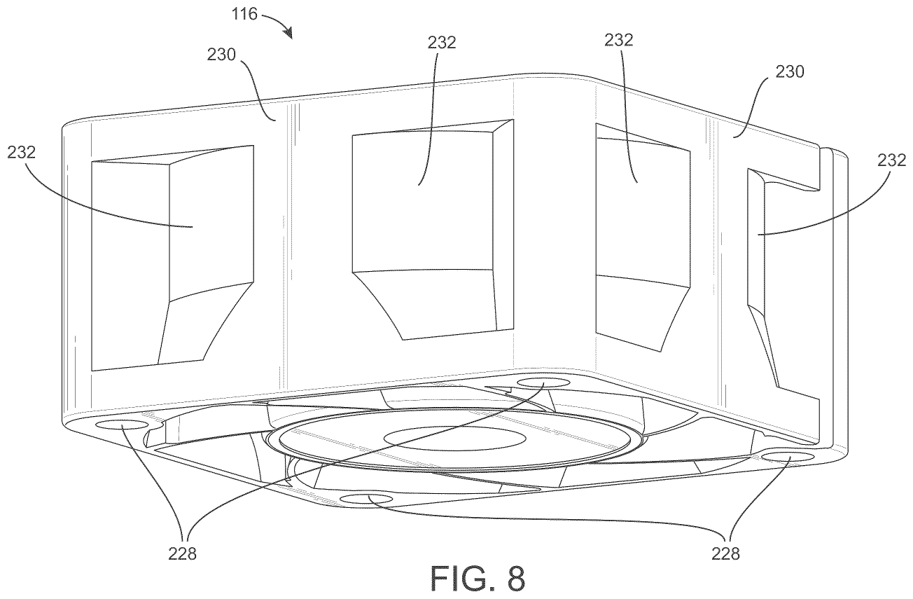

FIGS. 7 and 8 illustrate the fan assembly 116 in further detail. The fan body 120 includes a central portion 216 defining a fan hub 218, a central bore 220, a plurality of blades 222, and an annular blade cavity 224. The fan body 120 further includes fan corners 226. The fan corners 226 include corner bores 228. The corner bores 228 are configured to receive fasteners to fixedly attach the fan body 120 to other objects such as the control electronics 114, the motor housing 78, or a support bracket. The blades 222 extend radially from the central portion 216. The fan output shaft 123 (FIG. 5) of the fan motor 121 extends through the central bore 220. The fan hub 218 may be fixed to the fan output shaft 123 such that the fan hub 218 rotates with the fan output shaft 123 when the fan motor 121 is actuated, and the fan output shaft 123 is thereby rotated. In the illustrated embodiment, the fan assembly 116 includes seven blades 222. In other embodiments, the fan assembly 116 may include more than or less than seven blades 222. The blades 222 are fixed to the fan hub 218 such that rotation of the fan hub 218 results in a rotation of the blades 222, and the rotation of the blades 222 generates airflow in the forward direction along the fan axis 115. The fan body 120 is disposed around the fan blades 222. The fan body 120 surrounds the fan blades 222 to direct airflow from a rear of the fan to a front of the fan assembly 116 toward the control electronics 114. The fan body 120 includes four sides 230, and each includes a plurality of recesses 232. Each recess 232 defines an outer surface of the annular blade cavity 224 and the corner bores 228. In alternate embodiments, the fan body 120 may include more or less recesses 232. In the present embodiment, the blades 222 are integrally formed with the fan hub 218. In other embodiments, the blades 222 may be secured to the fan hub 218 by other means (e.g., fasteners, adhesive, press fit, etc.).

In alternate embodiments, the fan body 120 may include a front grill or filter disposed on a front side of the fan body 120 and a rear grill or filter disposed on a rear side of the fan body 120. The front grill and the rear grill would allow airflow to pass therethrough while inhibiting objects and/or debris that may damage the blades 222 from entering the fan body 120. In still other embodiments, the fan assembly 116 may have other configurations.

During operation, when the drain cleaning device 10 is in use, the fan blades 222 rotate and generate airflow within an interior of the drain cleaning device 10 to cool the control electronics 114 and other internal components within the motor housing 78.

Although the invention has been described in detail with reference to certain preferred embodiments, variations and modifications exist within the scope and spirit of one or more independent aspects of the invention as described.

What is claimed is:

1. A drain cleaning device comprising:
a frame;
a drum assembly supported for rotation on the frame about an axis of rotation;
a motor supported by the drum assembly, the motor having an output shaft defining a motor axis;
control electronics supported by the drum assembly, the control electronics defining a control electronics axis that is oblique to the motor axis; and
a fan assembly supported by the drum assembly, the fan assembly defining a fan axis, the fan axis being parallel to the control electronics axis, the fan assembly operable to induce an airflow along the fan axis and the control electronics axis.

2. The drain cleaning device of claim 1, further comprising a flexible cable at least partially received in the drum assembly and coupled to the output shaft to receive torque from the motor.

3. The drain cleaning device of claim 1, wherein the control electronics and the fan assembly are coupled together.

4. The drain cleaning device of claim 1, wherein the fan axis is offset from the axis of rotation.

5. The drain cleaning device of claim 1, wherein the drum assembly includes a housing, and wherein the motor, the control electronics, and the fan assembly are disposed in the housing.

6. The drain cleaning device of claim 1, wherein the fan assembly includes a fan motor that induces the airflow.

7. The drain cleaning device of claim 1, wherein the drum assembly includes an inner drum with an open front end and a closed rear end.

8. The drain cleaning device of claim 7, wherein the motor, the control electronics, and the fan assembly are supported on an inner surface of the inner drum.

9. The drain cleaning device of claim 1, further comprising a battery receptacle supported by the drum assembly, the battery receptacle configured to receive a battery pack that supplies power to the motor and to the fan assembly.

10. A drain cleaning device comprising:
a frame;
a drum assembly supported by the frame, the drum assembly configured to rotate about an axis of rotation;
a housing supported by the drum assembly;
a motor disposed within the housing, the motor having an output shaft defining a motor axis;
control electronics disposed within the housing, the control electronics defining a control electronics axis; and
a fan assembly disposed within the housing along the control electronics axis, the fan assembly operable to induce an airflow along the control electronics axis.

11. The drain cleaning device of claim 10, further comprising a battery receptacle supported by the drum assembly, the battery receptacle configured to receive a battery pack that supplies power to the motor and to the fan assembly.

12. The drain cleaning device of claim 11, wherein the battery receptacle is positioned on a diametrically opposite side of the axis of the rotation from the motor.

13. The drain cleaning device of claim 10, wherein the fan assembly is driven by a fan motor.

14. The drain cleaning device of claim 10, wherein the motor axis intersects the control electronics axis at an oblique angle.

15. A drum assembly including:
an outer drum;
an inner drum coupled for co-rotation with the outer drum, the outer drum and the inner drum defining a space therebetween;
a motor supported by the inner drum, the motor including an output shaft defining a motor axis;
control electronics supported by the inner drum, the control electronics defining a control electronics axis;
a fan assembly supported by the inner drum along the control electronics axis;
a flexible cable at least partially stored within the space; and
a battery receptacle supported by the drum assembly, the battery receptacle configured to receive a battery pack that supplies power to the motor and to the fan assembly;
wherein the control electronics axis intersects the motor axis at an oblique angle.

16. The drum assembly of claim 15, wherein a first end of the flexible cable is coupled to the output shaft to receive torque from the motor.

17. The drum assembly of claim 15, wherein the fan assembly includes a fan motor that induces an airflow along the control electronics axis.

18. The drum assembly of claim 15, wherein the fan assembly defines a fan axis, and wherein the fan axis and the control electronics axis are offset from an axis of rotation of the drum assembly.

19. The drum assembly of claim 18, wherein the fan axis is parallel to the control electronics axis.

20. The drum assembly of claim 15, wherein the inner drum and the outer drum are each cylindrically shaped with an open front end and a closed rear end.
